(19) United States
(12) Patent Application Publication
(10) Pub. No.: US 2024/0412427 A1
(43) Pub. Date: Dec. 12, 2024

(54) Information Display System

(71) Applicant: Daifuku Co., Ltd., Osaka-shi (JP)

(72) Inventors: Daisuke Ogawa, Hinocho (JP); Kenshin Hashiguchi, Hinocho (JP); Daichi Tomida, Hinocho (JP)

(21) Appl. No.: 18/736,222

(22) Filed: Jun. 6, 2024

(30) Foreign Application Priority Data
Jun. 7, 2023 (JP) 2023-094120

(51) Int. Cl. G06T 11/20; G07C 5/02

(52) U.S. Cl. CPC G06T 11/206; G07C 5/02

(57) ABSTRACT

An information display device includes a recording device that records transport vehicle travel data including position information about a transport vehicle and vibration information about the transport vehicle in an associated manner and path map data of a map of a travel path of the transport vehicle. The information display device includes a control device that displays the path map data on a first display area, displays a transport vehicle mark indicating a position of the transport vehicle at a target display time point on the map displayed on the first display area, displays a vibration result graph showing the vibration information at and around the target display time point on a second display area, and displays a position mark indicating a position on the vibration result graph corresponding to the target display time point on the second display area.

### CROSS-REFERENCE TO RELATED APPLICATION

This application claims priority to Japanese Patent Application No. 2023-094120 filed Jun. 7, 2023, the disclosure of which is hereby incorporated by reference in its entirety.

### BACKGROUND OF THE INVENTION

### Field of the Invention

The present invention relates to an information display system including a display device for displaying information, a control device for controlling the display device, and a recording device.

### Description of Related Art

An example of such an information display system is described in Patent Literature 1 (Japanese Unexamined Patent Application Publication No. 2016-52919) below. In the background described hereafter, reference signs and names in parentheses are the reference signs and the names in Patent Literature 1.

An information display system in Patent Literature 1 includes a display device (display 128) for displaying information and a recording device (storage 123) in which position information indicating positions of a transport vehicle (112) and times at which the transport vehicle are at the positions are recorded in an associated manner. The display device (128) displays a transport vehicle mark (transport vehicle icon 133) indicating the position of the transport vehicle (112) corresponding to a predetermined time on a map (path map 132) of a travel path of the transport vehicle (112).

The storage (123) also stores state information indicating the state of the transport vehicle (112) associated with the time at which the state information is obtained. The display device (128) also includes, in addition to a display area for the map (132) of the travel path for the transport vehicle (112) and the transport vehicle mark (133) described above, a display area for a state graph (134) that visually shows sequential changes in the state information corresponding to a predetermined time.

In Patent Literature 1, the state information indicating the state of the transport vehicle (112) includes information such as the state of an operation mode of the transport vehicle (112), an abnormality code indicating the type of abnormality, detection states of multiple parcel sensors attached to a lift mount (114), information about whether a parcel is on the lift mount (114), values output from encoders corresponding to a front wheel and to a rear wheel in a carriage (113), speed obtained from the values output from the encoders and time information from a timer, and a value of voltage output from a battery mounted on the transport vehicle (112).

For a traveling transport vehicle, the degree of vibration measured in the transport vehicle is useful information. For example, information about a portion in a travel path of the transport vehicle in which larger vibration is measured allows identification of the portion of the travel path with potential abnormality. However, the technique described in Patent Literature 1 does not obtain information about vibration in the transport vehicle as state information indicating the state of the transport vehicle.

With the technique in Patent Literature 1, the state graph simply shows sequential changes in the state information within a predetermined period. Thus, a viewer of the state graph cannot identify a portion in the state graph indicating the state at a predetermined time corresponding to the position of the transport vehicle mark. In other words, in checking the state at a specific time in the sequentially changing state information shown in the state graph, a portion of the travel path including the traveling transport vehicle at the time is not identified easily.

### SUMMARY OF THE INVENTION

An information display system that facilitates determination of the relationship between the shape or structure of the travel path of the transport vehicle and vibration is thus awaited.

In response to the above, an information display device system includes a display device that displays information, a control device that controls the display device, and a recording device. The recording device records transport vehicle travel data and path map data. The transport vehicle travel data is data including, in an associated manner, position information indicating a position of a transport vehicle and vibration information indicating vibration measured in the transport vehicle. The path map data is data of a map of a travel path on which the transport vehicle has traveled. The control device defines a first display area and a second display area in a display screen of the display device. The control device performs a map display process of displaying, on the first display area, at least part of the map based on the path map data, a transport vehicle display process of displaying a transport vehicle mark indicating a position of the transport vehicle at a target display time point on the map displayed on the first display area through the map display process, a graph display process of displaying a vibration result graph showing the vibration information at least at and around the target display time point on the second display area, and a position mark display process of displaying a position mark indicating a position on the vibration result graph corresponding to the target display time point on the second display area.

In this structure, through the map display process and the transport vehicle display process, the map of the travel path and a position on the map for the transport vehicle at the target display time point are displayed on the first display area in the display screen of the display device. Through the graph display process and the position mark display process, the vibration result graph showing the vibration information at least at and around the target display time point and the position mark indicating a position on the vibration result graph corresponding to the target display time point are displayed on the second display area in the display screen of the display device. In other words, the viewer of the display screen including the first display area and the second display area can visually and easily determine the features of the measured vibration in the transport vehicle at positions on the travel path. The information display system thus facilitates determination of the relationship between the shape or structure of the travel path shown in the map and the vibration.

### BRIEF DESCRIPTION OF THE DRAWINGS

FIG. 1 is a plan view of an article transport facility in which a vibration measurement device measures vibration.

FIG. 2 is a side view of a transport vehicle including the vibration measurement device.

FIG. 3 is a schematic block diagram of the transport vehicle and the vibration measurement device.

FIG. 4 is a diagram describing the operation of guide wheels.

FIG. 5 is a diagram describing the operation of the guide wheels.

FIG. 6 is a diagram describing a detection area for an object detection sensor in the transport vehicle.

FIG. 7 is a diagram describing the detection area for the object detection sensor in the transport vehicle.

FIG. 8 is a diagram of an information display system, describing its structure.

FIG. 9 is a diagram of an example display screen of a display device.

FIG. 10 is a diagram of an example display screen of the display device.

FIG. 11 is a diagram of an example display screen of the display device.

FIG. 12 is a diagram of an example display screen of the display device.

FIG. 13 is a diagram of an example display screen of the display device.

FIG. 14 is a diagram of an example display screen of the display device.

FIG. 15 is a diagram of an example display screen of the display device.

### DESCRIPTION OF THE INVENTION

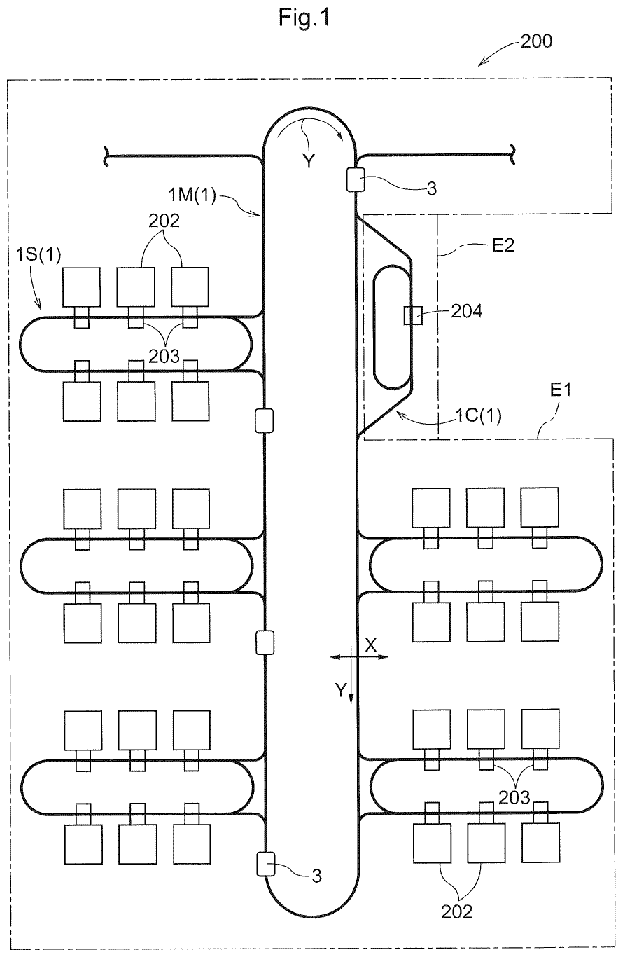

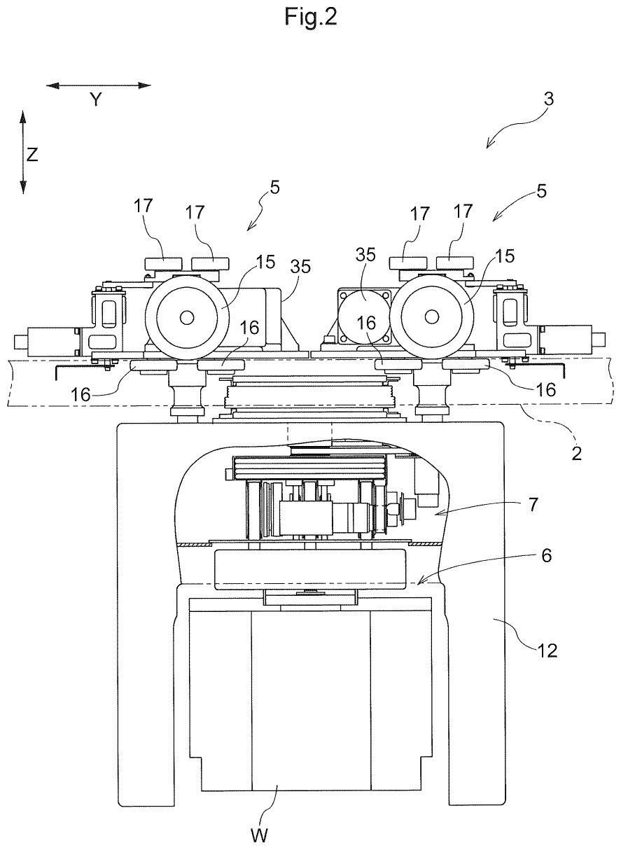

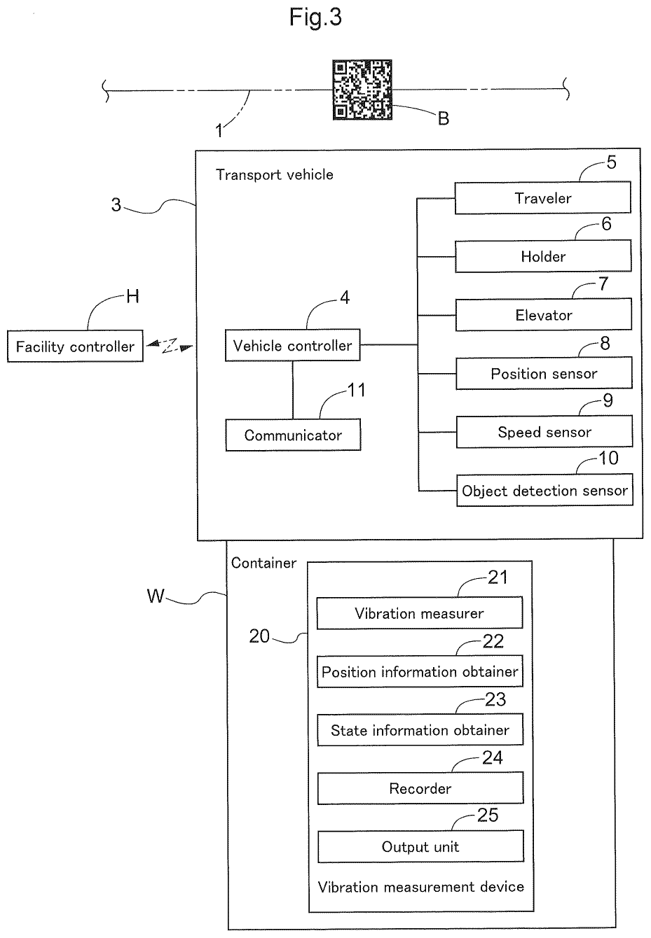

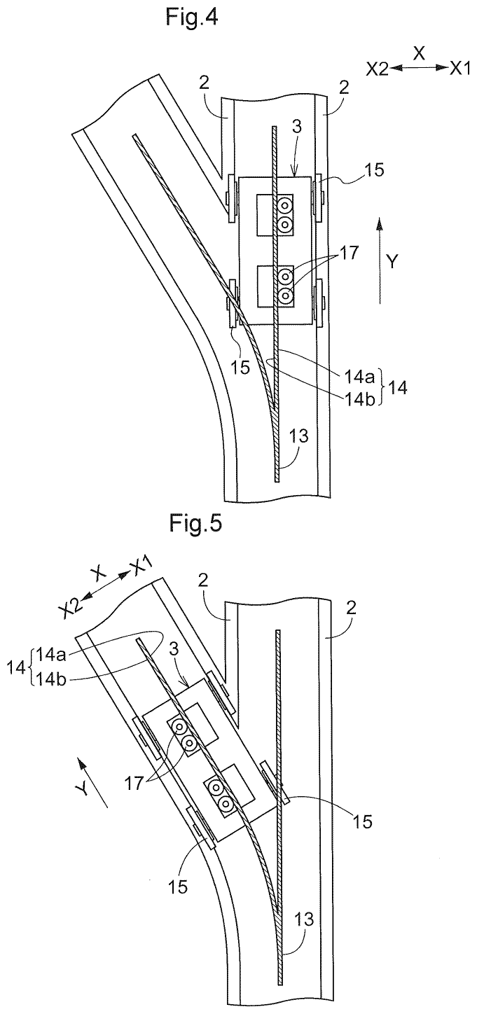

An information display system according to an embodiment will now be described with reference to the drawings. In the present embodiment, an example information display system displays information output from a vibration measurement device 20 mounted on a transport vehicle 3 that transports an article. In the example described below, the vibration measurement device 20 is mounted on the transport vehicle 3 for transporting an article, and measures vibration. FIG. 1 is a plan view of an article transport facility 200 in which the vibration measurement device 20 measures vibration. FIG. 2 is a side view of the transport vehicle 3 including the vibration measurement device 20. FIG. 3 is a schematic block diagram of the transport vehicle 3 and the vibration measurement device 20. FIGS. 4 and 5 are diagrams describing the operation of guide wheels 17 included in the transport vehicle 3. The direction along a travel path 1 is hereafter referred to as a travel direction Y, and the direction parallel to a horizontal plane and perpendicular to the travel direction Y is hereafter referred to as a width direction X.

A vertical direction Z is a direction perpendicular to the travel direction Y and to the width direction X.

The article transport facility 200 includes travel rails 2 hung from the ceiling and installed along the travel path 1 and the transport vehicles 3 that are hung from the travel rails 2 and travel on the travel rails 2 along the travel path 1 to transport containers W. In other words, the transport vehicles 3 described in the present embodiment are ceiling-hung transport vehicles. The transport vehicles 3 transport, for example, front opening unified pods (FOUPs) containing articles, such as wafers being materials for semiconductor substrates, as the containers W.

As shown in FIG. 1, the travel path 1 includes, for example, an annular primary path IM, multiple annular secondary paths 1S through multiple processing devices 202, and a maintenance path IC included in a maintenance area E2 (described later). The travel path 1 is one-way. The transport vehicles 3 travel on the travel path 1 from upstream to downstream in the travel direction Y. The travel path 1 includes a transport area E1 and the maintenance area E2. The transport vehicles 3 travel in the transport area E1 when transporting the containers W and in the maintenance area E2 when undergoing maintenance. The maintenance area E2 includes, for example, a maintenance lifter 204 for lowering a transport vehicle 3 hung from the travel rails 2 toward the ground for maintenance. As shown in FIGS. 4 and 5, the transport vehicles 3 are guided with a pair of the travel rails 2.

The processing devices 202 are, for example, semiconductor processing devices for performing various processes such as an exposure process and an etching process. In this case, the FOUPs described above are transported as the containers W in the article transport facility 200. The containers W and the articles contained in the containers W may be other containers and articles. For example, the articles may be reticles used in the exposure process of a wafer in the manufacturing process of a semiconductor substrate, and the transport vehicles 3 may transfer reticle pods containing reticles as the containers W. Each processing device 202 also includes a mount 203.

As shown in FIG. 2, each transport vehicle 3 includes travelers 5 and a transport vehicle body 12. The travelers 5 travel along the travel path 1 while being guided by the travel rails 2 hung from the ceiling along the travel path 1. The transport vehicle body 12 below the travel rails 2 is hung from the travelers 5. The transport vehicle 3 also includes a holder 6 for hanging and holding the container W and an elevator 7 for lifting and lowering the holder 6. As shown in FIG. 2, the transport vehicle 3 travels with the holder 6 being lifted and transports the container W.

As shown in FIGS. 2, 4, and 5, each traveler 5 includes a pair of travel wheels 15 that are rotatably drivable by an electric travel actuator 35. The travel actuator 35 is, for example, a motor (travel motor). The travel wheels 15 roll on the upper surfaces of the travel rails 2 that serve as traveling surfaces. Although not shown in detail, the traveler 5 includes a pair of auxiliary wheels 16 that are freely rotatable about axes parallel to the vertical direction Z. The auxiliary wheels 16 are in contact with the inner surfaces of the travel rails 2 in the pair.

As shown in FIGS. 4 and 5, the travel path 1 includes a guide rail 13 extending in the travel direction Y of the transport vehicles 3 in its branching section. Although not shown, the travel path 1 also includes a similar guide rail 13 in its merging section. The guide rail 13 has a pair of guide surfaces 14 (a first guide surface 14a and a second guide surface 14b). The pair of guide surfaces 14 (the first guide surface 14a and the second guide surface 14b) face in the opposite directions in the width direction X, which is perpendicular to the travel direction Y, and extend in the travel direction Y. Each transport vehicle 3 includes the guide wheels 17 that are rotatable about vertical axes parallel to the vertical direction Z. The guide wheels 17 can change their positions to the right or to the left of the guide rail 13 located in the middle of the pair of left and right travel rails 2. The guide wheels 17 rotate while being in contact with the first guide surface 14a that is a right guide surface 14 of the guide rail 13 or with the second guide surface 14b that is a left guide surface 14.

As described below, each transport vehicle 3 includes a vehicle controller 4 that causes the travelers 5 to perform a switching operation of causing, in the branching section and in the merging section, the guide wheels 17 to be in contact with either the guide surfaces 14 in the pair.

In the example in FIG. 4, the transport vehicle 3 heading in the travel direction Y travels to a path on the right (or moves straight in this example) in the branching section. In this case, the vehicle controller 4 causes the guide wheels 17 to be on the first guide surface 14a of the guide rail 13 (on the right in the travel direction Y). The transport vehicle 3 thus travels with the guide wheels 17 in contact with the first guide surface 14a of the guide rail 13. As shown in FIG. 4, as the transport vehicle 3 moves straight on the path on the right (in a first width direction X1) in the branching section, one of the left and right travel rails 2 (the left travel rail 2 herein) ends, causing the travel wheels 15 and the auxiliary wheels 16 on the left to be derailed. The auxiliary wheels 16 are not shown in FIG. 4 for simplicity. However, the guide rail 13 receiving the load of the transport vehicle 3 through the guide wheels 17 supports and guides the transport vehicle 3. Thus, the transport vehicle 3 does not fall off the travel rail 2 and can travel straight in the branching section.

In the example in FIG. 5, the transport vehicle 3 heading in the travel direction Y travels to a path on the left (or moves sideways along the curved path in this example) in the branching section. In this case, the vehicle controller 4 causes the guide wheels 17 to be on the second guide surface 14b of the guide rail 13 (on the left in the travel direction Y). The transport vehicle 3 is thus guided with the guide wheels 17 in contact with the second guide surface 14b of the guide rail 13. As shown in FIG. 5, as the transport vehicle 3 moves sideways on the path on the left (in a second width direction X2) in the branching section, one of the left and right travel rails 2 (the right travel rail 2 herein) ends, causing the travel wheels 15 and the auxiliary wheels 16 on the right to be derailed. However, the guide rail 13 receiving the load of the transport vehicle 3 through the guide wheels 17 supports and guides the transport vehicle 3. Thus, the transport vehicle 3 does not fall off the travel rail 2 and can travel sideways in the branching section.

As shown in FIG. 3, the transport vehicle 3 includes a position sensor 8, a speed sensor 9, an object detection sensor 10, and a communicator 11, in addition to the components described above.

The vehicle controller 4 controls the operation of the transport vehicle 3. For example, the vehicle controller 4 can communicate information wirelessly with a facility controller H, which manages the entire article transport facility 200, through the communicator 11. The vehicle controller 4 causes the transport vehicle 3 to travel, transport the container W between different mounts 203, stop above a specified mount 203, and then lower and lift the holder 6 to transfer the container W through autonomous control in response to a transport command from the facility controller H.

The position sensor 8 detects the position of the transport vehicle 3. For example, as shown in FIG. 3, multiple position indicators B indicating positions on the travel path 1 are located along the travel path 1. The position indicators B can be, for example, one- or two-dimensional barcodes or markers with numbers or characters. The position sensor 8 can be a barcode reader, an image recognition device, or a character recognition device that recognizes numbers and characters. The position sensor 8 can derive the distance traveled by the transport vehicle 3 using, for example, a sensor for detecting the rotation angle of a wheel axle (not shown) of the travel wheels 15. The position sensor 8 can then detect the current position of the transport vehicle 3 on the travel path 1 based on the distance traveled by the transport vehicle 3 after detection of the position indicator B. The position information detected by the position sensor 8 is transmitted to the vehicle controller 4. In this manner, the transport vehicle 3 can detect its position on the travel path 1 using the multiple position indicators B. The transport vehicle 3 transmits the detected position information sequentially to the facility controller H, and the facility controller H can transmit a transport command generated based on the position information to the transport vehicle 3.

The speed sensor 9 detects the travel speed of the transport vehicle 3. The speed sensor 9 can be implemented by, for example, a sensor for detecting the rotation angle of the wheel axle (not shown) of the travel wheels 15. In this case, the speed sensor 9 derives the rotational speed of the wheel axle based on the rotation angle of the wheel axle (not shown) of the travel wheels 15, and then can derive the travel speed of the transport vehicle 3. The speed sensor 9 may transmit the derived travel speed to the vehicle controller 4. Alternatively, the speed sensor 9 may sequentially transmit the measured rotation angles of the wheel axle (not shown) of the travel wheels 15 to the vehicle controller 4, and the vehicle controller 4 may derive the travel speed of the transport vehicle 3 based on the value of the rotation angle.

The object detection sensor 10 detects an object that blocks a traveling transport vehicle 3. For example, multiple transport vehicles 3 travel on the travel path 1 at the same time. To avoid collisions between the transport vehicles 3, each transport vehicle 3 includes the object detection sensor 10 that detects an object in a predetermined area defined ahead in the travel direction Y.

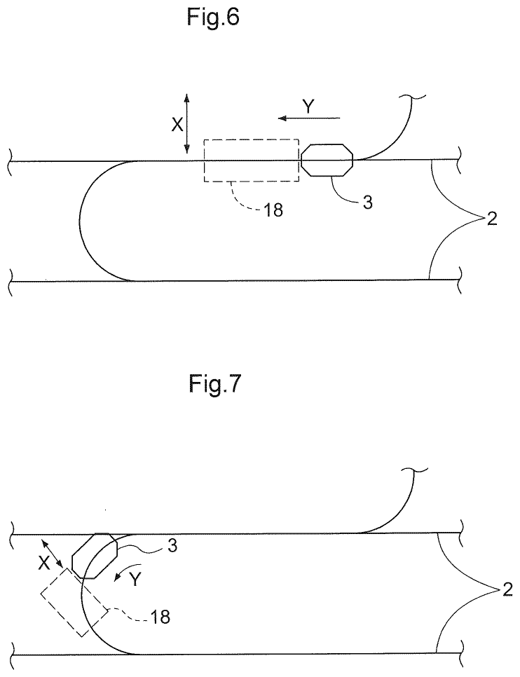

FIGS. 6 and 7 are diagrams describing a detection area 18 for the object detection sensor 10 in the transport vehicle 3. As shown in FIG. 6, for the transport vehicle 3 heading to a straight section in the travel direction Y, the detection area 18 defined ahead of the transport vehicle 3 in the travel direction Y has a shape longer in the travel direction Y than in the width direction X. As shown in FIG. 7, for the transport vehicle 3 heading to a curved section in the travel direction Y, the detection area 18 defined ahead of the transport vehicle 3 in the travel direction Y has a shape longer in the width direction X than in the travel direction Y based on the shape of the curved travel path 1.

The vibration measurement device 20 mounted on the transport vehicle 3 will now be described. As shown in FIG. 3, the vibration measurement device 20 includes a vibration measurer 21, a position information obtainer 22, a state information obtainer 23, a recorder 24, and an output unit 25. The vibration measurer 21 measures vibration. The position information obtainer 22 obtains position information indicating the position of the transport vehicle 3. The state information obtainer 23 obtains vehicle state information indicating the state of the transport vehicle 3. The recorder 24 records measurement results from the vibration measurer 21, the vehicle state information, and the position information in an associated manner. The output unit 25 outputs information recorded in the recorder 24. The vibration measurement device 20 has, for example, an information communication function, an information computation processing function, and an information storage function. As described later, the vibration measurement device 20 may use at least part of these functions to implement the functions of the vibration measurer 21, the position information obtainer 22, the state information obtainer 23, the recorder 24, and the output unit 25. The vibration measurement device 20 may be implemented by a single device having these functions or multiple devices having these functions.

The vibration measurer 21 can be implemented by a sensor that can measure the physical quantities of vibration, such as amplitude, frequency, and acceleration of the vibration. The vibration measurer 21 may measure vibration in three directions perpendicular to one another, such as the X-, Y-, and Z-directions. The vibration measurer 21 may measure vibration in one or two directions of the X-, Y-, and Z-directions. The vibration measurer 21 may obtain, in addition to the measurement results of vibration, time information about the time at which the measurement results are obtained.

The position information obtainer 22 obtains position information indicating the position of the transport vehicle 3. For example, the position information obtainer 22 uses the information communication function of the vibration measurement device 20 to obtain the position information about the transport vehicle 3 detected by the position sensor 8 in the transport vehicle 3. The position information obtainer 22 may obtain information about the time at which the position information is detected in addition to the position information.

The state information obtainer 23 obtains vehicle state information indicating the state of the transport vehicle 3. For example, the state information obtainer 23 uses the information communication function of the vibration measurement device 20 to obtain the vehicle state information measured by the transport vehicle 3. The state information obtainer 23 may obtain time information about the time at which the vehicle state information is measured, together with the vehicle state information.

The vehicle state information includes at least one of the travel speed of the transport vehicle 3, the acceleration state of the transport vehicle 3, the operation state of an operation assembly included in the transport vehicle 3, or the detection state of the sensor (e.g., the object detection sensor 10) included in the transport vehicle 3.

The travel speed of the transport vehicle 3 is a value measured by the speed sensor 9 in the transport vehicle 3. The acceleration state (specifically, the acceleration indicating an increasing speed, a decreasing speed, or a constant speed) of the transport vehicle 3 is determined by computing changes in the travel speed measured by the speed sensor 9 in the transport vehicle 3. The vehicle controller 4 in the transport vehicle 3 may compute the acceleration state of the transport vehicle 3, and the state information obtainer 23 in the vibration measurement device 20 may obtain the computed acceleration state. Alternatively, the state information obtainer 23 in the vibration measurement device 20 may use the computation processing function of the vibration measurement device 20 to compute the acceleration state based on the obtained travel speed of the transport vehicle 3. For example, an accelerating or decelerating transport vehicle 3 vibrates relatively largely, and a transport vehicle 3 traveling at a constant speed vibrates relatively slightly.

The operation state of the operation assembly included in the transport vehicle 3 is information about the operation state of the operation assembly in the transport vehicle 3, such as the travelers 5, the holder 6, and the elevator 7. For example, the transport vehicle 3 includes the guide wheels 17 shown in FIGS. 4 and 5 as a part of each traveler 5. The operation of the guide wheels 17 is controlled by the vehicle controller 4. The state information obtainer 23 can obtain, from the vehicle controller 4 in the transport vehicle 3, information indicating that the guide wheels 17 are on the right or on the left in the travel direction Y. The operation state is not limited to the state of the guide wheels 17 (in other words, the travelers 5). For example, the operation state may include the operation state of the elevator 7 and the operation state of the holder 6. When the guide wheels 17 in the travelers 5 operate (specifically, when the guide wheels 17 change their positions between the left and the right), for example, the transport vehicle 3 may vibrate relatively largely.

The detection state of the object detection sensor 10 included in the transport vehicle 3 is, for example, information about the shape of the detection area 18 for the object detection sensor 10 shown in FIGS. 6 and 7 or information about whether an object is detected. The state of the detection area 18 for the object detection sensor 10 in the transport vehicle 3 is controlled by the vehicle controller 4. Information about whether the object detection sensor 10 has detected an object is transmitted to the vehicle controller 4. The state information obtainer 23 can obtain information about the detection state of the object detection sensor 10 in the transport vehicle 3 from the vehicle controller 4 in the transport vehicle 3. When the object detection sensor 10 detects an object, for example, the transport vehicle 3 decelerates. This may cause the transport vehicle 3 to vibrate relatively largely.

As described above, the state information obtainer 23 can obtain, as the vehicle state information, information indicating behavior of the transport vehicle 3 that possibly affects vibration measured by the vibration measurer 21. Thus, the user referring to the vehicle state information can easily perform analysis to determine whether the vibration is greatly affected by the state of the transport vehicle 3.

The recorder 24 records the measurement results (vibration information) from the vibration measurer 21, the vehicle state information, and the position information in an associated manner. The recorder 24 can be implemented using the information storage function of the vibration measurement device 20. When the measurement results from the vibration measurer 21, the vehicle state information, and the position information are each associated with the time information as described above, for example, the recorder 24 can record the measurement results from the vibration measurer 21, the vehicle state information, and the position information obtained at the same time or within a predetermined time range in an associated manner. When items in the above information are not associated with the time information, the recorder 24 may record the measurement results from the vibration measurer 21, the vehicle state information, and the position information recorded at the same time or within the predetermined time range as one dataset in an associated manner.

The vibration information may be information about the physical quantities of vibration, such as the amplitude, frequency, and acceleration of the vibration measured by the vibration measurer 21, or values computed from such physical quantities. For example, the vibration information may include an effective value (root-mean-square or RMS) computed using a vibration waveform.

In this manner, the recorder 24 can record transport vehicle travel data that is data including, in an associated manner, at least the position information indicating the position of the transport vehicle 3 and the vibration information indicating the vibration measured in the transport vehicle 3 or transport vehicle travel data that is data including, in an associated manner, at least the position information indicating the position of the transport vehicle 3, the vibration information indicating the vibration measured in the transport vehicle 3, and the vehicle state information indicating the state of the transport vehicle 3. The position information, the vibration information, and the vehicle state information included in the transport vehicle travel data may be associated with the time information. The recorder 24 can record, as path map data, information about the positions through which the transport vehicle 3 has traveled. The path map data includes map data of the travel path 1 on which the transport vehicle 3 has traveled. The information about the positions through which the transport vehicle 3 has traveled may be associated with the time information.

The output unit 25 outputs information recorded in the recorder 24. For example, the output unit 25 uses the information communication function of the vibration measurement device 20 to output information recorded in the recorder 24 to another device that can communicate with the vibration measurement device 20. In addition to outputting information by transmitting the information to other devices, the output unit 25 may output information, for example, to a display device 41 for displaying, to paper for printing, or to a portable storage.

As described above, the vibration measurement device 20 according to the present embodiment can obtain information indicating vibration measured at positions on the travel path 1 on which the transport vehicle 3 has traveled and the state of the transport vehicle 3 at the positions.

Thus, the user receiving the output information can appropriately obtain information such as a position on the travel path 1 of the transport vehicle 3 at which vibration is larger and the state of the transport vehicle 3 when vibration is larger. In other words, the vibration measurement device 20 according to the present embodiment can output information for allowing appropriate analysis of the cause of the measured vibration.

The information display system will now be described.

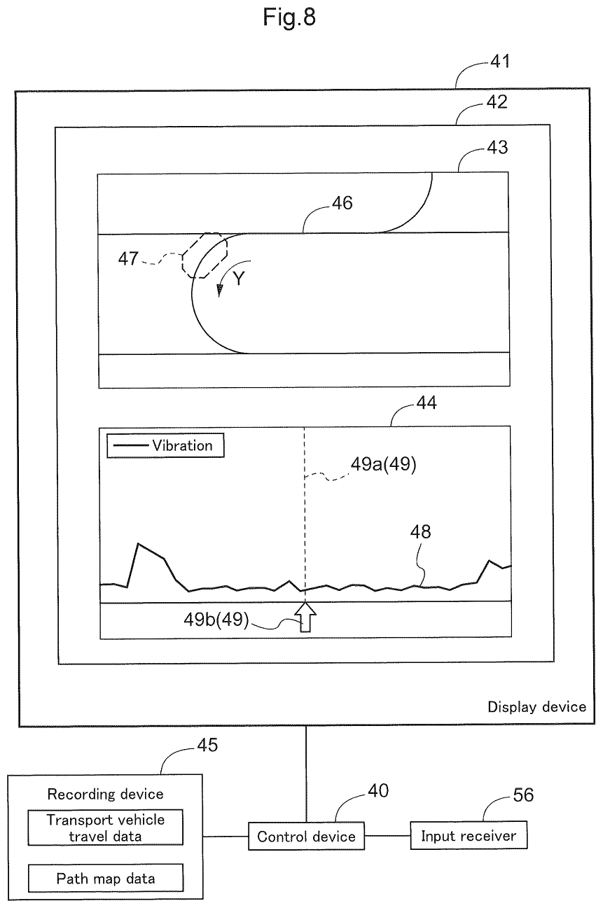

FIG. 8 is a diagram of the information display system, describing its structure. As illustrated, the information display system includes a display device 41 for displaying information, a control device 40 for controlling the display device 41, a recording device 45, and an input receiver 56. The information display system can be implemented by one or more computer devices that have, for example, an information display function (specifically, the display device 41 above), an information communication function, an information computation function (specifically, the control device 40 above), an information recording function (specifically, the recording device 45 above), and an information input receiver function (specifically, the input receiver 56 above) such as a keyboard or a mouse.

The recording device 45 records the transport vehicle travel data and the path map data. The transport vehicle travel data includes, in an associated manner, the position information indicating the position of the transport vehicle 3 and the vibration information indicating the vibration measured in the transport vehicle 3. The path map data includes the map data of the travel path 1 on which the transport vehicle 3 has traveled (specifically, information about the positions through which the transport vehicle 3 has traveled). In other words, the transport vehicle travel data is associated with the path map data at the positions of the transport vehicle 3 at respective time points during the travel. Thus, when the position of the transport vehicle 3 at a specific time point is specified, the vibration information at the time point is identified, and a portion of the map of the travel path 1 corresponding to the position is also identified.

The transport vehicle travel data and the path map data recorded in the recording device 45 include data output from the output unit 25 in the vibration measurement device 20. When a computer device for implementing the information display system can communicate information with the vibration measurement device 20, for example, information included in the transport vehicle travel data and the path map data may be output from the output unit 25 in the vibration measurement device 20 to the computer device for implementing the information display system. Alternatively, the output unit 25 in the vibration measurement device 20 can output information included in the transport vehicle travel data and the path map data to a portable storage. The portable storage is then connected to the computer device for implementing the information display system, and the recorded information is read. In this manner, the recording device 45 can record the information included in the transport vehicle travel data and the path map data.

The control device 40 defines a first display area 43 and a second display area 44 in a display screen 42 of the display device 41 and performs a map display process, a transport vehicle display process, a graph display process, and a position mark display process described later.

The map display process is to display, on the first display area 43, at least part of the map based on the path map data. In the example shown in FIG. 8, a travel path mark 46 corresponding to the travel path 1 is displayed. For example, the control device 40 can display the travel path mark 46 with a line connecting the positions through which the transport vehicle 3 has traveled. When the map information about the travel path 1 is already available or, for example, when the travel rails 2 are installed, the control device 40 may display the travel path map with the travel path mark 46.

The transport vehicle display process is to display a transport vehicle mark 47 indicating the position of the transport vehicle 3 at a target display time point on the map (travel path mark 46) displayed on the first display area 43 through the map display process. In the example shown in FIG. 8, the control device 40 displays the transport vehicle mark 47 at a position corresponding to the position of the transport vehicle 3 at the specific time point (specifically, the target display time point) in the travel path map. The travel path map is displayed with the travel path mark 46 based on the path map data that is the map data of the travel path 1 on which the transport vehicle 3 has traveled (specifically, information about the positions through which the transport vehicle 3 has traveled). The transport vehicle mark 47 can have any shape or pattern as appropriate.

The graph display process is to display a vibration result graph 48 showing the vibration information at least at and around the target display time point on the second display area 44. In the example shown in FIG. 8, the control device 40 displays the vibration result graph 48 showing the changes in the vibration information at and around the specific time point (specifically, the target display time point) based on the transport vehicle travel data including, in an associated manner, the position information indicating the position of the transport vehicle 3 and the vibration information indicating the vibration measured in the transport vehicle 3.

The position mark display process is to display a position mark 49 indicating a position on the vibration result graph 48 corresponding to the target display time point on the second display area 44. In the example shown in FIG. 8, the control device 40 displays a dashed line 49a indicating the target display time point and an arrow 49b pointing at the dashed line 49a as the position mark 49. The position mark 49 can have any shape or pattern as appropriate.

In this manner, through the map display process and the transport vehicle display process, the map of the travel path 1 and the position on the map for the transport vehicle 3 at the target display time point are displayed on the first display area 43 in the display screen 42 of the display device 41. Through the graph display process and the position mark display process, the vibration result graph 48 showing the vibration information at least at and around the target display time point and the position mark 49 indicating a position on the vibration result graph 48 corresponding to the target display time point are displayed on the second display area 44 in the display screen 42 of the display device 41. In other words, a viewer of the display screen 42 including the first display area 43 and the second display area 44 can visually and easily determine the features of measured vibration in the transport vehicle 3 at positions on the travel path 1. This can provide the information display system that facilitates determination of the relationship between the shape or structure of the travel path 1 shown in the map and the vibration.

The transport vehicle travel data may further include travel speed information indicating the travel speed of the transport vehicle 3. The travel speed information may be associated with the position information and the vibration information. The control device 40 may perform a replay display process of moving, in the transport vehicle display process, the transport vehicle mark 47 relative to the map at a speed corresponding to the travel speed of the transport vehicle 3 based on the transport vehicle travel data and moving, in the position mark display process, the position mark 49 relative to the vibration result graph 48 at a speed corresponding to the moving speed of the transport vehicle mark 47. Alternatively, the control device 40 may move the transport vehicle mark 47 relative to the map at a constant speed independent of the travel speed of the transport vehicle 3.

Although not shown, the control device 40 may display, for example, a replay control button such as a replay start button or a replay stop button on the display screen 42 and may perform the replay display process in response to an input operation (specifically, an instruction of displaying, or for example, starting and stopping, a replay) by the user operating the input receiver 56 such as a mouse. Alternatively, the control device 40 may automatically perform the replay display process without an input operation on the replay start button by the user.

When the map display process, the transport vehicle display process, and the replay display process described above are performed, the map of the travel path 1 and the transport vehicle mark 47 indicating the position on the map for the transport vehicle 3 at the target display time point are displayed on the first display area 43 in the display screen 42 of the display device 41. The transport vehicle mark 47 also moves relative to the map at a speed corresponding to the travel speed of the transport vehicle 3 based on the transport vehicle travel data. When the graph display process, the position mark display process, and the replay display process are performed, the vibration result graph 48 showing the vibration information at least at and around the target display time point and the position mark 49 indicating a position on the vibration result graph 48 corresponding to the target display time point are displayed on the second display area 44 in the display screen 42 of the display device 41. The position mark 49 also moves relative to the vibration result graph 48 at a speed corresponding to the travel speed of the transport vehicle 3 based on the transport vehicle travel data. In other words, the viewer of the display screen 42 including the first display area 43 and the second display area 44 can visually and easily determine the speed of the moving transport vehicle 3 and changes in the values of vibration in the transport vehicle 3 at positions on the travel path 1.

In the first display area 43, the control device 40 can perform, for example, a replay display process of moving, with the display position of the transport vehicle mark 47 being fixed, the travel path mark 46 indicating the travel path map, a replay display process of moving, with the travel path mark 46 indicating the travel path map being fixed, the display position of the transport vehicle mark 47, or a replay display process of moving both the display position of the transport vehicle mark 47 and the travel path mark 46 indicating the travel path map.

In the second display area 44, the control device 40 can perform, for example, a replay display process of moving, with the display position of the position mark 49 indicating the target display time point being fixed, the vibration result graph 48, a replay display process of moving, with the display position of the vibration result graph 48 being fixed, the display position of the position mark 49 indicating the target display time point, or a replay display process of moving both the display position of the position mark 49 indicating the target display time point and the vibration result graph 48.

In response to the user's instruction received by the input receiver 56, for example, the control device 40 can change information items to be displayed on the first display area 43 and the second display area 44. Some examples of the display screen in the first display area 43 and the second display area 44 will be described below.

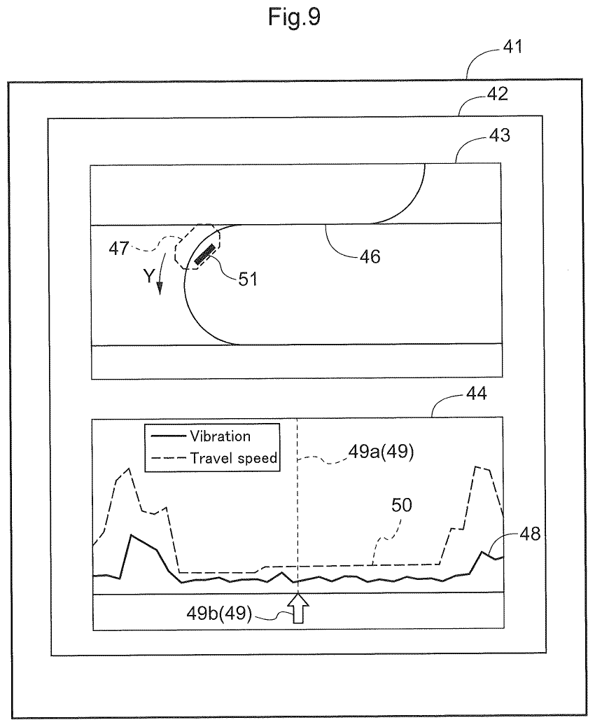

FIG. 9 is a diagram of an example display screen of the display device 41. In this example, the transport vehicle travel data further includes the vehicle state information indicating the state of the transport vehicle 3. The vehicle state information is associated with the position information and the vibration information. The control device 40 displays, in the graph display process, the vehicle state graph 50 indicating the vehicle state information at least at and around the target display time point on the second display area 44 together with the vibration result graph 48, and displays, in the position mark display process, a position on the vehicle state graph 50 corresponding to the target display time point on the second display area 44 using the position mark 49.

In the example shown in FIG. 9, the travel speed of the transport vehicle 3 is the vehicle state information.

In the graph display process, the control device 40 displays the vibration result graph 48 showing changes in the vibration information at and around a specific time point (specifically, the target display time point) and the vehicle state graph 50 showing changes in the travel speed based on the transport vehicle travel data including, in an associated manner, information about the travel speed of the transport vehicle 3 (the vehicle state information), the position information, the vibration information. In this manner, the viewer of the display screen 42 including the first display area 43 and the second display area 44 can visually and easily determine the features of measured vibration in the transport vehicle 3 and the state of the transport vehicle 3 at positions on the travel path 1. This can facilitate determination of the relationship between the shape or structure of the travel path 1 shown in the map, the vibration, and the state of the transport vehicle 3.

Although the vibration result graph 48 and the vehicle state graph 50 are displayed on the single second display area 44 in FIG. 9, the display screen 42 may include multiple second display areas 44, for example, and the vibration result graph 48 and the vehicle state graph 50 may be displayed on the respective second display areas 44. In this case, the position mark 49 may also be displayed on each of the second display area 44.

The control device 40 also performs a vehicle state display process of displaying a vehicle state mark 51 indicating the vehicle state information on the map displayed through the map display process. The vehicle state mark 51 is displayed in a manner corresponding to the transport vehicle mark 47 displayed through the transport vehicle display process.

In the example shown in FIG. 9, the vehicle state information indicates the operation state of the guide wheels 17 (specifically, indicates that the guide wheels 17 heading in the travel direction Y is located on either the right or the left). In the vehicle state display process, the control device 40 displays the vehicle state mark 51 indicating the operation state of the guide wheels 17 on the map displayed thorough the map display process. The vehicle state mark 51 is displayed in a manner corresponding to the transport vehicle mark 47 displayed through the transport vehicle display process. The control device 40 displays the vehicle state mark 51 based on the transport vehicle travel data including, in an associated manner, information about the operation state of the guide wheels 17 (the vehicle state information), the position information, and the vibration information. In the shown example, the guide wheels 17 heading in the travel direction Y is located on the left. In this manner, the viewer of the display screen 42 including the first display area 43 and the second display area 44 can visually and easily determine the features of the measured vibration in the transport vehicle 3 and the state of the guide wheels 17 in the transport vehicle 3 at positions on the travel path 1.

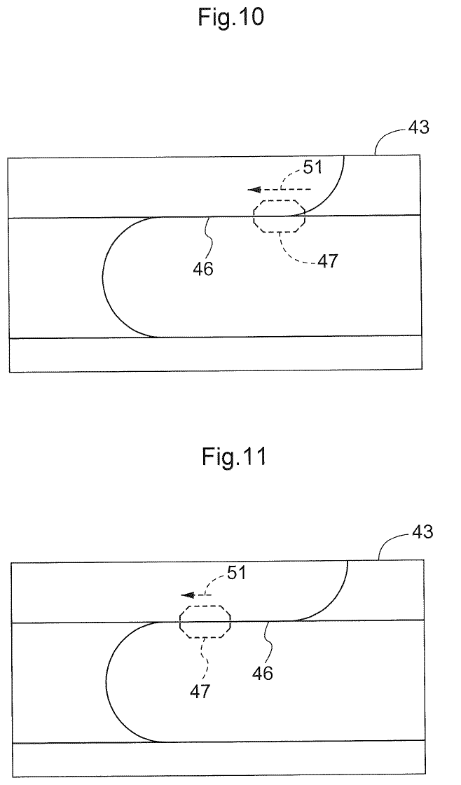

FIGS. 10 and 11 are diagrams of example display screens of the display device 41. In each example, the transport vehicle travel data further includes the vehicle state information indicating the state of the transport vehicle 3. The vehicle state information is associated with the position information and the vibration information. The control device 40 further performs the vehicle state display process of displaying the vehicle state mark 51 indicating the vehicle state information on the map displayed through the map display process. The vehicle state mark 51 is displayed in a manner corresponding to the transport vehicle mark 47 displayed through the transport vehicle display process.

In the examples shown in FIGS. 10 and 11, the vehicle state information includes the travel speed of the transport vehicle 3. The control device 40 displays, in the vehicle state display process, the vehicle state mark 51 indicating the travel speed of the transport vehicle 3 on the map displayed through the map display process. The vehicle state mark 51 is displayed in a manner corresponding to the transport vehicle mark 47 displayed through the transport vehicle display process. The control device 40 displays the vehicle state mark 51 based on data including, in an associated manner, information about the travel speed of the transport vehicle 3 (the vehicle state information), the position information, and the vibration information. For example, in each of FIGS. 10 and 11, the travel speed of the transport vehicle 3 as the vehicle state information is displayed by a dashed arrow as the vehicle state mark 51. A longer dashed arrow indicates a higher travel speed. In other words, with the dashed arrow as the vehicle state mark 51 longer in FIG. 10 than in FIG. 11, the transport vehicle 3 at the time point in FIG. 10 travels at a higher travel speed. In this manner, the viewer of the display screen 42 including the first display area 43 and the second display area 44 can visually and easily determine the features of the measured vibration in the transport vehicle 3 and the state of the travel speed of the transport vehicle 3 at positions on the travel path 1.

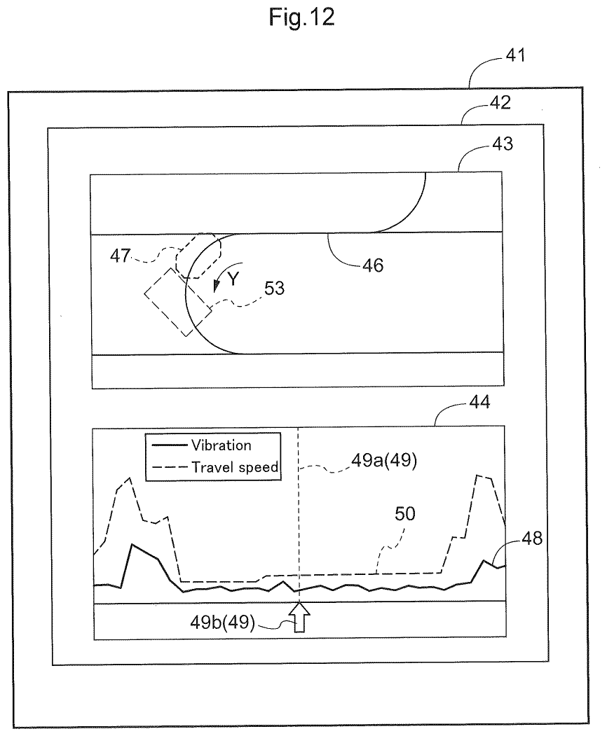

FIG. 12 is a diagram of an example display screen of the display device 41. In this example, the transport vehicle travel data further includes detection area information indicating the state of the detection area 18 for the object detection sensor 10 in the transport vehicle 3. The detection area information is associated with the position information and the vibration information. The control device 40 further performs, based on the transport vehicle travel data, a detection area display process of displaying a detection area mark 53 indicating the state of the detection area 18 at the target display time point on the map displayed through the map display process. The detection area mark 53 is displayed in a manner corresponding to the transport vehicle mark 47 displayed through the transport vehicle display process. In FIG. 12, for example, the horizontal shape of the detection area 18 as the vehicle state information is displayed with a dashed-line shape as the detection area mark 53. The detection area mark 53 in FIG. 12 has the same shape as the detection area 18 in FIG. 7. In this manner, the viewer of the display screen 42 including the first display area 43 and the second display area 44 can visually and easily determine the feature of measured vibration in the transport vehicle 3 and the state of the detection area 18 for the object detection sensor 10 in the transport vehicle 3 at positions on the travel path 1. The detection area mark 53 can have any shape or pattern as appropriate.

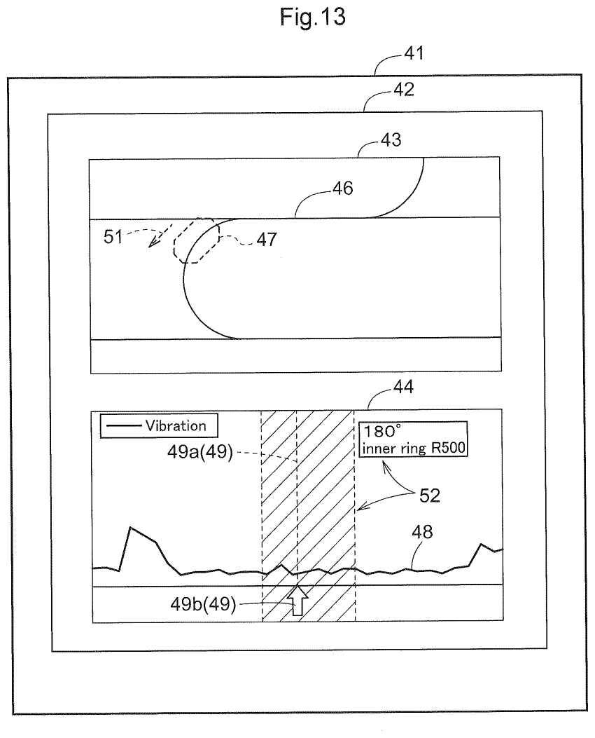

FIG. 13 is a diagram of an example display screen of the display device 41. In this example, the control device 40 further performs a path shape display process of displaying, on the second display area 44, path shape indication 52 indicating the shape of the travel path 1 on which the transport vehicle 3 has traveled. The path shape indication 52 corresponds to a position at which vibration shown in the vibration result graph 48 is measured. In the example shown in FIG. 13, the second display area 44 has a different pattern in part (in a portion corresponding to a curved section of the travel path 1). The path shape indication 52 indicating 180° inner ring R500 is displayed. This indication means that the curved section is the travel path 1 curved 180° around the inner ring with a curvature radius of 500 mm. In this manner, the viewer of the display screen 42 including the second display area 44 can visually and easily determine the relationship between the shape of the travel path 1 and the vibration.

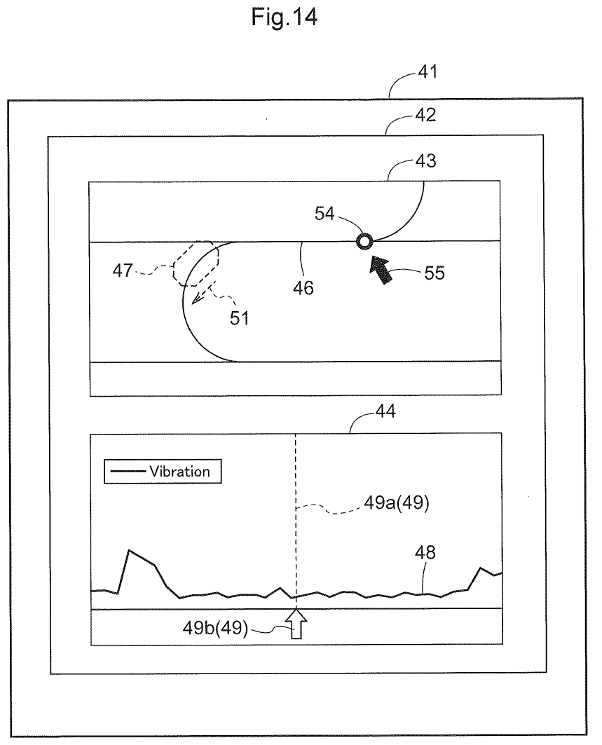

FIG. 14 is a diagram of an example display screen of the display device 41. In this example, the control device 40 performs a vibration point mark display process of displaying, on the map, a vibration point mark 54 indicating a point on the travel path 1 at which a value of vibration indicated by the vibration information exceeds a predetermined determination threshold. A mouse pointer 55 is also displayed on the first display area 43. In this manner, the viewer of the first display area 43 can easily determine a point on the travel path 1 at which larger vibration occurs. The vehicle state mark 51 indicating the travel speed of the transport vehicle 3 is also displayed on the first display area 43 in FIG. 14.

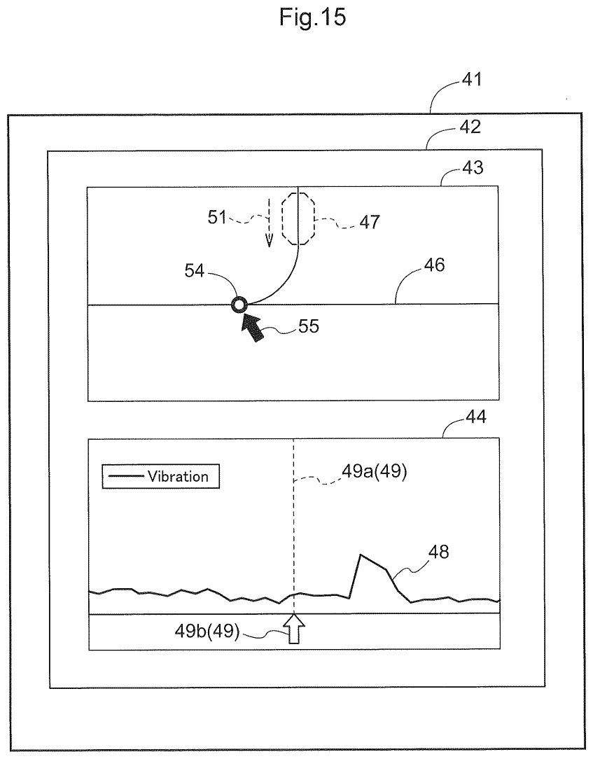

The control device 40 can further perform an operation reception process of receiving the operation of selecting a vibration point mark 54 displayed through the vibration point mark display process. For example, the user operating the input receiver 56 such as a mouse can select a specific vibration point mark 54 with the mouse pointer 55. In response to the operation of selecting the vibration point mark 54 being received through the operation reception process, the control device 40 starts the replay display process from a point upstream from the point indicated by the vibration point mark 54 as shown in FIG. 15.

In this manner, in response to the operation on the vibration point mark 54 being received, a replay from the point upstream from the point indicated by the vibration point mark 54 is displayed through the replay display process. Thus, the display device 41 can display information that may facilitate determination of the shape or structure of the travel path 1 adjacent to a point on the travel path 1 at which the transport vehicle 3 vibrates relatively largely and the travel speed of the transport vehicle 3.

An information display system according to other embodiments will now be described.

(1) In the above embodiment, the transport vehicles 3 are ceiling-hung transport vehicles. In some embodiments, the transport vehicles 3 may be automatic guided vehicles (AGVs), sorting transfer vehicles (STVs), stacker cranes, or autonomous mobile robots (AMRs).

(2) In the above embodiment, the position sensor 8 detects the position of the transport vehicle 3 based on the position indicator B indicating a position on the travel path 1. The position sensor 8 may detect the position of the transport vehicle 3 with another method. For example, the position sensor 8 may receive signals from global navigation satellite system (GNSS) satellites included in the GNSS and detect the position of the transport vehicle 3.

(3) In the above embodiment, the vehicle state information may include different items as appropriate. For example, the vehicle state information may include information about the detection state of various sensors included in the transport vehicles 3. Examples of the various sensors in the transport vehicles 3 include a sensor that detects the operation state of the holder 6 for holding the container W and a sensor that detects the operation state of the elevator 7 for lifting and lowering the holder 6.

(4) Although the first display area 43 is clearly separate from the second display area 44 in the display screen 42 in the above embodiment, the first display area 43 and the second display area 44 can be displayed on the display screen 42 in any appropriate manner. For example, the first display area 43 and the second display area 44 may partially overlap on the display screen 42. Another display area other than the first display area 43 or the second display area 44 may be displayed on the display screen 42.

(5) In the above embodiment, in response to an instruction by the user operating the input receiver 56, the control device 40 may, for example, enlarge or reduce the map of the travel path 1 displayed on the first display area 43 and the graph or other diagrams displayed on the second display area 44, or may move them in the vertical direction or the lateral direction.

(6) In the above embodiment, the graph displayed on the second display area 44 can have any horizontal axis defined as appropriate to allow tracking of changes in the information displayed on the second display area 44. For example, the horizontal axis may be the sum of the distance traveled by the transport vehicle 3 or the order in which information items have been recorded.

(7) In the above embodiment, the details of the replay display process may be changed as appropriate. When the user provides an instruction by selecting and moving the transport vehicle mark 47 using the input receiver 56 such as a mouse (specifically, by dragging the transport vehicle mark 47 with the mouse) on the first display area 43, for example, the control device 40 may perform the replay display process of moving the transport vehicle mark 47 relative to the map (travel path mark 46) in response to the instruction and also moving the position mark 49 relative to the vibration result graph 48 on the second display area 44 accordingly.

(8) In the above embodiment, although the vehicle state mark 51 indicating the travel speed of the transport vehicle 3 is displayed as a dashed arrow in FIGS. 10 and 11, the vehicle state mark 51 may be displayed in any appropriate manner. For example, numerical values indicating the travel speed of the transport vehicle 3 (in other words, text information) may be displayed as the vehicle state mark 51.

(9) The structure described in each of the above embodiments may be combined with any other structures described in the other embodiments unless any contradiction arises. For other structures as well, the embodiments described herein are merely illustrative in all respects and may be modified variously as appropriate without departing from the spirit and scope of the disclosure.

In one embodiment, an information display device system includes a display device that displays information, a control device that controls the display device, and a recording device. The recording device records transport vehicle travel data and path map data. The transport vehicle travel data is data including, in an associated manner, position information indicating a position of a transport vehicle and vibration information indicating vibration measured in the transport vehicle. The path map data is data of a map of a travel path on which the transport vehicle has traveled. The control device defines a first display area and a second display area in a display screen of the display device. The control device performs a map display process of displaying, on the first display area, at least part of the map based on the path map data, a transport vehicle display process of displaying a transport vehicle mark indicating a position of the transport vehicle at a target display time point on the map displayed on the first display area through the map display process, a graph display process of displaying a vibration result graph showing the vibration information at least at and around the target display time point on the second display area, and a position mark display process of displaying a position mark indicating a position on the vibration result graph corresponding to the target display time point on the second display area.

In this structure, through the map display process and the transport vehicle display process, the map of the travel path and a position on the map for the transport vehicle at the target display time point are displayed on the first display area in the display screen of the display device. Through the graph display process and the position mark display process, the vibration result graph showing the vibration information at least at and around the target display time point and the position mark indicating a position on the vibration result graph corresponding to the target display time point are displayed on the second display area in the display screen of the display device. In other words, the viewer of the display screen including the first display area and the second display area can visually and easily determine the features of the measured vibration in the transport vehicle at positions on the travel path. The information display system thus facilitates determination of the relationship between the shape or structure of the travel path shown in the map and the vibration.

In one embodiment, the transport vehicle travel data further includes vehicle state information indicating a state of the transport vehicle. The vehicle state information is associated with the position information and the vibration information. In the graph display process, the control device displays, together with the vibration result graph, a vehicle state graph showing the vehicle state information at least at and around the target display time point on the second display area. In the position mark display process, the control device displays a position on the vehicle state graph corresponding to the target display time point on the second display area using the position mark.

In this structure, through the graph display process and the position mark display process, the vehicle state graph showing the vehicle state information at least at and around the target display time point is displayed on the second display area in the display screen of the display device, together with the vibration result graph and the position mark indicating a position on the vibration result graph corresponding to the target display time point. In other words, the viewer of the display screen including the first display area and the second display area can visually and easily determine the features of measured vibration in the transport vehicle and the state of the transport vehicle at positions on the travel path. This can facilitate determination of the relationship between the shape or the structure of the travel path shown in the map, the vibration, and the state of the transport vehicle.

In one embodiment, the transport vehicle travel data further includes vehicle state information indicating a state of the transport vehicle. The vehicle state information is associated with the position information and the vibration information. The control device further performs a vehicle state display process of displaying a vehicle state mark indicating the vehicle state information on the map displayed through the map display process. The vehicle state mark is displayed in a manner corresponding to the transport vehicle mark displayed through the transport vehicle display process.

In this structure, through the vehicle state display process, the position of the transport vehicle at the target display time point displayed by the transport vehicle mark and the state of the transport vehicle at the target display time point displayed by the vehicle state mark are displayed on the first display area in the display screen of the display device. In other words, the viewer of the display screen including the first display area and the second display area can visually and easily determine the features of measured vibration in the transport vehicle and the state of the transport vehicle at positions on the travel path.

In one embodiment, the vehicle state information includes at least one of a travel speed of the transport vehicle, an acceleration state of the transport vehicle, an operation state of a traveler included in the transport vehicle, or a detection state of a sensor included in the transport vehicle.

In this structure, through the graph display process and the position mark display process, the vehicle state graph showing the vehicle state information at least at and around the target display time point is displayed on the second display area in the display screen of the display device, together with the vibration result graph and the position mark indicating a position on the vibration result graph corresponding to the target display time point. The vehicle state information includes at least one of the travel speed of the transport vehicle, the acceleration state of the transport vehicle, the operation state of the traveler in the transport vehicle, or the detection state of the sensor in the transport vehicle. Each of the travel speed of the transport vehicle, the acceleration state of the transport vehicle, the operation state of the traveler in the transport vehicle, and the detection state of the sensor in the transport vehicle as the vehicle state information indicating the state of the transport vehicle may affect vibration measured in the transport vehicle. Thus, the viewer of the display screen including the second display area can visually and easily determine whether the state of the transport vehicle has caused the vibration.

In one embodiment, the control device further performs a path shape display process of displaying path shape indication indicating a feature of a shape of the travel path on which the transport vehicle has traveled on the second display area. The path shape indication is displayed in a manner corresponding to a position at which the vibration shown in the vibration result graph is measured.

In this structure, the viewer of the display screen including the second display area can visually and easily determine the relationship between the shape of the travel path and the vibration.

In one embodiment, the transport vehicle travel data further includes detection area information indicating a state of a detection area for an object detection sensor included in the transport vehicle. The detection area information is associated with the position information and the vibration information. The control device further performs a detection area display process of displaying a detection area mark indicating a state of the detection area on the map displayed through the map display process. The detection area mark is displayed in a manner corresponding to the transport vehicle mark displayed through the transport vehicle display process.

In this structure, through the detection area display process, the position of the transport vehicle at the target display time point displayed by the transport vehicle mark and the state of the detection area for the object detection sensor at the target display time point are displayed on the first display area in the display screen of the display device. In other words, the viewer of the display screen including the first display area and the second display area can visually and easily determine the features of measured vibration in the transport vehicle and the state of the detection area for the object detection sensor in the transport vehicle at positions on the travel path.

In one embodiment, the transport vehicle travel data further includes travel speed information indicating a travel speed of the transport vehicle. The travel speed information is associated with the position information and the vibration information. The control device performs a replay display process of moving, in the transport vehicle display process, the transport vehicle mark relative to the map at a speed corresponding to the travel speed of the transport vehicle based on the transport vehicle travel data and moving, in the position mark display process, the position mark relative to the vibration result graph at a speed corresponding to a moving speed of the transport vehicle mark.

In this structure, through the map display process, the transport vehicle display process, and the replay display process, the map of the travel path and the transport vehicle mark indicating a position on the map for the transport vehicle at the target display time point are displayed on the first display area in the display screen of the display device. The transport vehicle mark also moves relative to the map at a speed corresponding to the travel speed of the transport vehicle based on the transport vehicle travel data. Through the graph display process, the position mark display process, and the replay display process, the vibration result graph showing the vibration information at least at and around the target display time point and the position mark indicating a position on the vibration result graph corresponding to the target display time point are displayed on the second display area in the display screen of the display device. The position mark also moves relative to the vibration result graph at a speed corresponding to the travel speed of the transport vehicle based on the transport vehicle travel data. In other words, the viewer of the display screen including the first display area and the second display area can visually and easily determine the speed of the moving transport vehicle and changes in the values of vibration in the transport vehicle at positions on the travel path.

In one embodiment, the control device further performs a vibration point mark display process of displaying, on the map, a vibration point mark indicating a point on the travel path at which a value of vibration indicated by the vibration information exceeds a predetermined determination threshold, an operation reception process of receiving an operation of selecting the vibration point mark displayed through the vibration point mark display process, and the replay display process from a point upstream from a point indicated by the vibration point mark in response to the operation of selecting the vibration point mark being received through the operation reception process.

In this structure, through the vibration point mark display process, the vibration point mark indicating a point on the map of the travel path at which the transport vehicle vibrates relatively largely is displayed on the first display area in the display screen of the display device. Thus, the viewer of the first display area can easily determine a point on the travel path at which larger vibration occurs. In this structure, in response to the operation on the vibration point mark being received, a replay from a point upstream from the point indicated by the vibration point mark is displayed through the replay display process. Thus, the display device can display information that may facilitate determination of the shape or structure of the travel path adjacent to the point on the travel path at which the transport vehicle vibrates relatively largely and the travel speed of the transport vehicle.

The information display system according to one or more embodiments of the disclosure may produce at least one of the effects described above.

### INDUSTRIAL APPLICABILITY

The technique according to one or more embodiments of the disclosure can be used in an information display system that facilitates determination of the relationship between the shape or structure of a travel path for a transport vehicle and vibration.

What is claimed is:

1. An information display device system, comprising:
a display device configured to display information;
a control device configured to control the display device; and
a recording device configured to record transport vehicle travel data and path map data, the transport vehicle travel data being data comprising, in an associated manner, position information indicating a position of a transport vehicle and vibration information indicating vibration measured in the transport vehicle, the path map data being data of a map of a travel path on which the transport vehicle has traveled,
the control device configured to define a first display area and a second display area in a display screen of the display device,
the control device configured to perform a map display process of displaying, on the first display area, at least part of the map based on the path map data,
a transport vehicle display process of displaying a transport vehicle mark indicating a position of the transport vehicle at a target display time point on the map displayed on the first display area through the map display process,
a graph display process of displaying a vibration result graph showing the vibration information at least at and around the target display time point on the second display area, and
a position mark display process of displaying a position mark indicating a position on the vibration result graph corresponding to the target display time point on the second display area.

2. The information display system according to claim 1, wherein:
the transport vehicle travel data further comprises vehicle state information indicating a state of the transport vehicle, and the vehicle state information is associated with the position information and the vibration information,
in the graph display process, the control device displays, together with the vibration result graph, a vehicle state graph showing the vehicle state information at least at and around the target display time point on the second display area, and
in the position mark display process, the control device displays a position on the vehicle state graph corresponding to the target display time point on the second display area using the position mark.

3. The information display system according to claim 1, wherein:
the transport vehicle travel data further comprises vehicle state information indicating a state of the transport vehicle, and the vehicle state information is associated with the position information and the vibration information, and
the control device further performs a vehicle state display process of displaying a vehicle state mark indicating the vehicle state information on the map displayed through the map display process, and the vehicle state mark is displayed in a manner corresponding to the transport vehicle mark displayed through the transport vehicle display process.

4. The information display system according to claim 2, wherein:
the vehicle state information comprises at least one of a travel speed of the transport vehicle, an acceleration state of the transport vehicle, an operation state of a traveler included in the transport vehicle, or a detection state of a sensor included in the transport vehicle.

5. The information display system according to claim 1, wherein:
the control device further performs a path shape display process of displaying path shape indication indicating a feature of a shape of the travel path on which the transport vehicle has traveled on the second display area, and the path shape indication is displayed in a manner corresponding to a position at which the vibration shown in the vibration result graph is measured.

6. The information display system according to claim 1, wherein:
the transport vehicle travel data further comprises detection area information indicating a state of a detection area for an object detection sensor included in the transport vehicle, and the detection area information is associated with the position information and the vibration information, and
the control device further performs a detection area display process of displaying a detection area mark indicating a state of the detection area on the map displayed through the map display process, and the detection area mark is displayed in a manner corresponding to the transport vehicle mark displayed through the transport vehicle display process.

7. The information display system according to claim 1, wherein:
the transport vehicle travel data further comprises travel speed information indicating a travel speed of the transport vehicle, and the travel speed information is associated with the position information and the vibration information, and
the control device performs a replay display process of moving, in the transport vehicle display process, the transport vehicle mark relative to the map at a speed corresponding to the travel speed of the transport vehicle based on the transport vehicle travel data and moving, in the position mark display process, the position mark relative to the vibration result graph at a speed corresponding to a moving speed of the transport vehicle mark.

8. The information display system according to claim 7, wherein:
the control device further performs a vibration point mark display process of displaying, on the map, a vibration point mark indicating a point on the travel path at which a value of vibration indicated by the vibration information exceeds a predetermined determination threshold,
an operation reception process of receiving an operation of selecting the vibration point mark is displayed through the vibration point mark display process, and
the replay display process from a point upstream from a point indicated by the vibration point mark in response to the operation of selecting the vibration point mark is received through the operation reception process.

9. The information display system according to claim 3, wherein:
the vehicle state information comprises at least one of a travel speed of the transport vehicle, an acceleration state of the transport vehicle, an operation state of a traveler included in the transport vehicle, or a detection state of a sensor included in the transport vehicle.
